(19) United States
(12) Patent Application Publication
(10) Pub. No.: US 2026/0253661 A1
(43) Pub. Date: Aug. 27, 2026

(54) MAC UNIT FUNCTIONAL SAFETY PROTECTION

(71) Applicant: Micron Technology, Inc., Boise, ID (US)

(72) Inventor: Steffen Buch, Taufkirchen (DE)

(21) Appl. No.: 19/541,856

(22) Filed: Feb. 17, 2026

Related U.S. Application Data
(60) Provisional application No. 63/762,994, filed on Feb. 25, 2025.

(51) Int. Cl. G11C 29/44; G06F 7/544

(52) U.S. Cl. CPC G11C 29/44; G06F 7/5443

(57) ABSTRACT

Apparatus and methods are disclosed, including reading operands for a processing in memory (PIM) operation from a memory array of the memory device; determining digital roots for the operands; determining a result of the PIM operation for the operands; determining the result of the PIM operation for the digital roots of the operands; determining a first result digital root for the result of the PIM operation for the operands; determining a second result digital root for the result of the PIM operation for the digital roots of the operands; and comparing the first result digital root and the second result digital root to detect an error in the PIM operation.

### PRIORITY APPLICATION

This application claims the benefit of priority to U.S. Provisional Application Ser. No. 63/762,994, filed Feb. 25, 2025, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data and includes devices such as random-access memory (RAM), static random-access memory (SRAM), dynamic random-access memory (DRAM), or synchronous dynamic random-access memory (SDRAM), among others.

Host systems typically include a host processor, a first amount of main memory (e.g., often volatile memory, such as DRAM) to support the host processor, and one or more memory systems (e.g., often non-volatile memory, such as flash memory, and may include volatile memory) that provide additional storage to retain data in addition to or separate from the main memory.

A memory system can include a memory controller and one or more memory devices, including a number of dies or logical units (LUNs). In certain examples, each die can include a number of memory arrays and peripheral circuitry thereon, such as die logic or a die processor. Some memory die can include processing memory (PIM) capability on the die to offload processing from other units of the computer system (e.g., central processing units or CPUs).

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a diagram of an example computing system including a host device and a memory system.

FIG. 2 is a block diagram of portions of an example of a memory device.

FIG. 3 is another block diagram of portions of an example of a memory device.

FIG. 4 is a circuit block diagram of an arithmetic circuit.

FIG. 5 is a flow diagram of an example of a method of operating a memory device.

FIG. 6 illustrates an example block diagram of an example machine.

### DETAILED DESCRIPTION

Software (e.g., programs), instructions, operating systems (OS), and other data are typically stored on storage systems and accessed for use by a host processor. Main memory (e.g., RAM) is typically faster, more expensive, and a different type of memory device (e.g., volatile) than a majority of the memory devices of the storage system (e.g., non-volatile, such as an SSD, etc.). In addition to the main memory, host systems can include different levels of volatile memory, such as a group of static memory (e.g., a cache, often SRAM), often faster than the main memory, in certain examples, configured to operate at speeds close to or exceeding the speed of the host processor, but with lower density and higher cost. Systems can also include processing in memory (PIM) capability. PIM can be used to perform processing on multiple memory locations to produce a result without the latency involved with transferring intermediate data over a link between the memory system processing resources of the computer system. Like memory storage operations, PIM operations may also by susceptible to errors resulting from radiation or faults in the memory array.

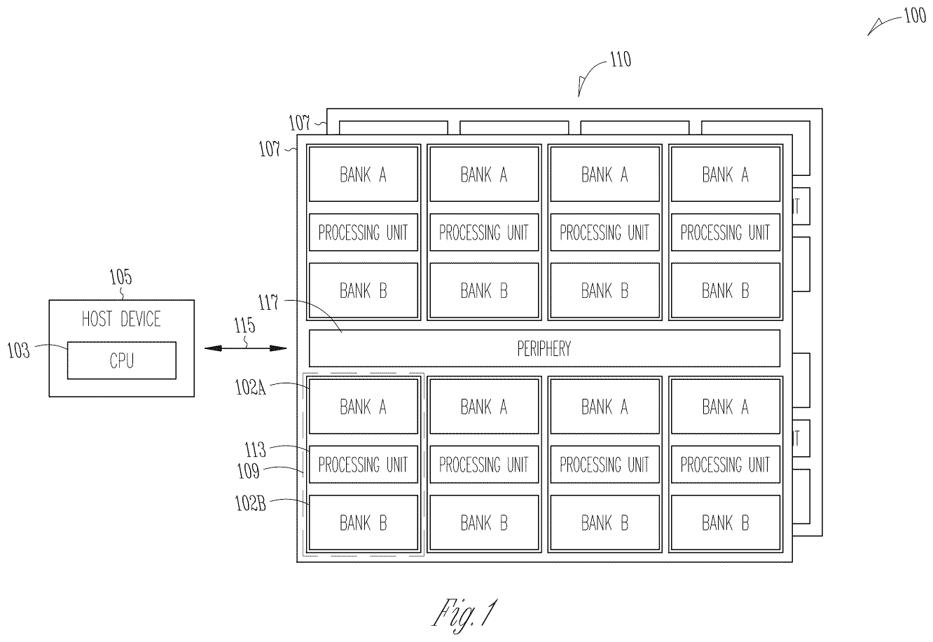

FIG. 1 is a block diagram of an example computing system 100 including a host device 105 and a memory system 110. The memory system 110 may include one or more memory devices 107. Each memory device 107 may be included on one memory die or multiple memory devices 107 can be included on one memory die.

The host device 105 and the memory system 110 communicate over a communication interface 115 (e.g., a bidirectional parallel or serial communication interface). The host device 105 can include a host processor 103 (e.g., a host central processing unit (CPU) or other processor or processing device) or other host circuitry (e.g., a memory management unit (MMU), interface circuitry, assessment circuitry, etc.). In certain examples, the host device 105 can include a main memory that includes DRAM to support operation of the host processor 103.

The memory devices 107 include processing in memory (PIM) blocks 109. In the example of FIG. 1, the memory devices 107 include eight PIM blocks 109, but an actual implementation a memory device 107 may include more than eight PIM blocks 109 or less than eight PIM blocks 109. Each PIM block 109 includes PIM circuitry. The PIM circuitry includes multiple memory banks 102A, 102B and processing units 113 (e.g., a processor or other processing circuitry). The PIM blocks 109 perform PIM operations on data stored in the memory banks 102A, 102B. Periphery circuitry 117 transfers data among the memory banks 102A, 102B, processing units 113, and communication interface 115.

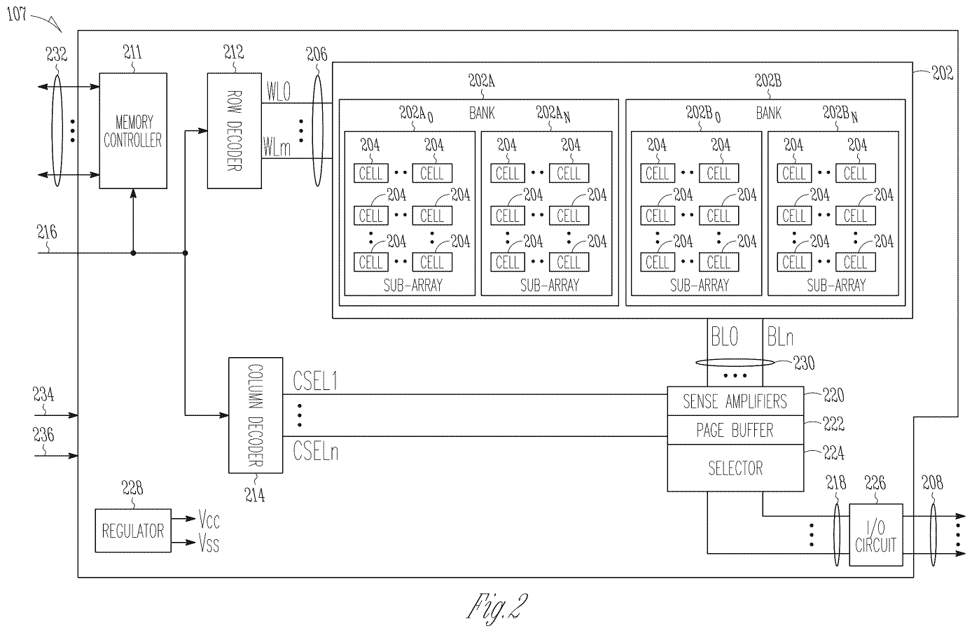

FIG. 2 illustrates an example block diagram of the memory portions of a memory device 107 including a memory array 202 having a plurality of memory cells 204, and one or more circuits or components to provide communication with, or perform one or more memory operations on, the memory array 202. Although shown with a single memory array 202, in other examples, one or more additional memory arrays, dies, or LUNs can be included herein. The memory device 107 can include a row decoder 212, a column decoder 214, sense amplifiers 220, a page buffer 222, a selector 224, an input/output (I/O) circuit 226, and a memory controller 211.

The memory cells 204 of the memory array 202 can be arranged in banks, such as first and second banks 202A, 202B. Each sector can include sub-sections or sub-arrays. For example, the first bank 202A can include first and second sub-arrays 202A₀, 202Aₙ, and the second bank 202B can include first and second sub-arrays 202B₀, 202Bₙ. Each sub-array can include a number of physical pages, each page including a number of memory cells 204. Although illustrated herein as having two banks, each block having two sub-arrays, and each sub-array having a number of memory cells 204, in other examples, the memory array 202 can include more or fewer banks, sub-arrays, memory cells, etc. In other examples, the memory cells 204 can be arranged in a number of rows, columns, pages, sub-arrays, banks, etc., and accessed using, for example, access lines 206, first data lines 230, or one or more select gates, source lines, etc.

The memory controller 211 can control memory operations of the memory device 107 according to one or more signals or instructions received on control lines 232, including, for example, one or more clock signals or control signals that indicate a desired operation (e.g., write, read, erase, etc.), or address signals (A0-AX) received on one or more address lines 216. One or more devices external to the memory device 107 can control the values of the control signals on the control lines 232, or the address signals on the address line 216. Examples of devices external to the memory device 107 can include, but are not limited to, a host, a memory controller, a processor, or one or more circuits or components not illustrated in FIG. 2.

The memory device 107 can use access lines 206 and first data lines 230 to transfer data to (e.g., write or erase) or from (e.g., read) one or more of the memory cells 204. The row decoder 212 and the column decoder 214 can receive and decode the address signals (A0-AX) from the address line 216, can determine which of the memory cells 204 are to be accessed, and can provide signals to one or more of the access lines 206 (e.g., one or more of a plurality of word lines (WL0-WLm)) or the first data lines 230 (e.g., one or more of a plurality of bit lines (BL0-BLn)), such as described above.

The memory device 107 can include sense circuitry, such as the sense amplifiers 220, configured to determine the values of data on (e.g., read), or to determine the values of data to be written to, the memory cells 204 using the first data lines 230. For example, in a selected string of memory cells 204, one or more of the sense amplifiers 220 can read a logic level in the selected memory cell 204 in response to a read current flowing in the memory array 202 through the selected string to the data lines 230.

One or more devices external to the memory device 107 can communicate with the memory device 107 using the I/O lines (DQ0-DQN) 208, address lines 216 (A0-AX), or control lines 232. The input/output (I/O) circuit 226 can transfer values of data in or out of the memory device 107, such as in or out of the page buffer 222 or the memory array 202, using the I/O lines 208, according to, for example, the control lines 232 and address lines 216. The page buffer 222 can store data received from the one or more devices external to the memory device 107 before the data is programmed into relevant portions of the memory array 202, or can store data read from the memory array 202 before the data is transmitted to the one or more devices external to the memory device 107.

The column decoder 214 can receive and decode address signals (A0-AX) into one or more column select signals (CSEL1-CSELn). The selector 224 (e.g., a select circuit) can receive the column select signals (CSEL1-CSELn) and select data in the page buffer 222 representing values of data to be read from or to be programmed into memory cells 204. Selected data can be transferred between the page buffer 222 and the I/O circuit 226 using second data lines 218.

The memory controller 111 can receive positive and negative supply signals, such as a supply voltage (Vcc) 234 and a negative supply (Vss) 236 (e.g., a ground potential), from an external source or supply (e.g., an internal or external battery, an AC-to-DC converter, etc.). In certain examples, the memory controller 111 can include a regulator 228 to internally provide positive or negative supply signals.

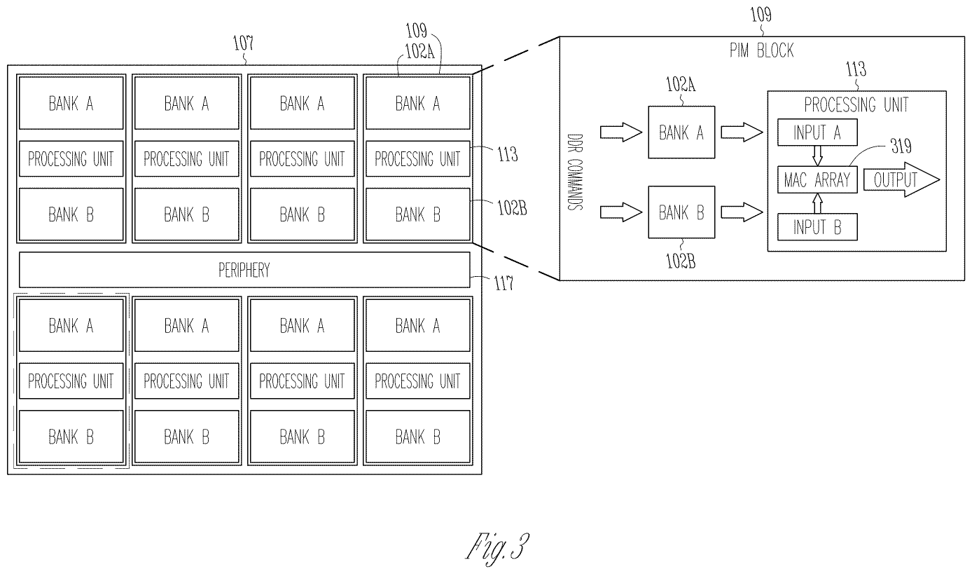

FIG. 3 is a circuit block diagram of portions of the example of a memory device 107 in FIG. 1 with an expanded diagram of a PIM block 109. The PIM block 109 performs a PIM operation as part of a memory command (e.g., DDR command) received from the host device 105. The processing unit 113 includes an arithmetic circuit 319. In the example of FIG. 3, the arithmetic circuit 319 includes multiply-accumulate (MAC) circuitry, but the arithmetic circuit 319 may perform any linear arithmetic operation. The MAC circuitry performs a MAC operation on operands stored in the memory banks. The MAC circuitry may receive a first operand or operands from memory bank 102A and a second operand or operands from memory bank 102B as inputs. The operands for the MAC operation may be designated in the memory command from the host device 105. The MAC circuitry produces an output that may be one or both of stored in the memory array and returned to the host device 105. The PIM block 109 may include error detection and correction circuitry to detect and correct memory errors for operands read from the memory. The error detection and correction circuitry can include one or both of error correcting code (ECC) circuitry (e.g., Hamming code circuitry), and error detecting code circuitry (e.g., cyclic redundancy check (CRC) circuitry). However, PIM blocks 109 may not include error detection and correction circuitry in the processing units 113.

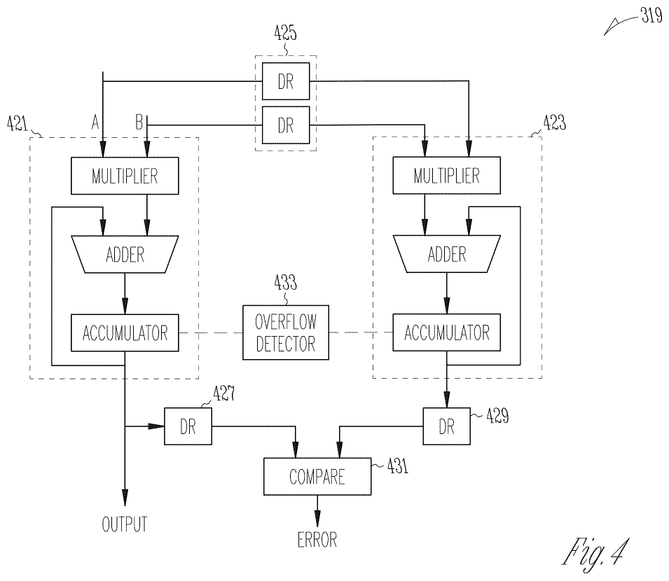

FIG. 4 is a circuit block diagram of an arithmetic circuit 319 of PIM circuitry of a PIM block 109. The arithmetic circuit 319 includes a first multiply-accumulate circuit 421 and includes error detection circuitry. The first multiply-accumulate circuit 421 performs MAC operations on the operands stored in the memory banks 102A, 102B. The multiply-accumulate circuitry 421 multiplies operand A and operand B using a multiplier circuit, and adds the result to an accumulator using an adder circuit. The accumulator holds the result of the previous multiply and add operations included in the MAC operation. The multiplier circuit may be a flow through multiplier circuit that multiplies the two digital operands A and B. In some examples, the multiplier circuit is a base-10 multiplier circuit that multiplies two base-10 numbers. Other number bases can be used. For instance, the multiplier circuit may be a base-16 multiplier circuit or a base-32 multiplier circuit.

The error detection circuitry includes a second multiply-accumulate circuit 423 and digital root (DR) circuitry 425, 427, 429. The digital root of a natural number is determined by repeatedly summing the digits of the number until only one digit remains. For example, the digital root of the number a=98765 equals 8(9+8+7+6+5=35, 3+5=8). A property of the digital root is that the digital root of the sum of two numbers is equal to the digital root of the sum of the digital roots of the two numbers or DR(a+b)=DR(DR(a)+DR(b)), where a and b are natural numbers. The same is true for multiplication. The digital root of the product of two numbers is equal to the product of the digital roots of the two numbers or DR(a*b)=DR(DR(a)*DR(b)).

In the example of FIG. 4, the first multiply-accumulate circuit 421 performs the operation Y=a*b+accu, where Y is the output and “accu” is the result in the accumulator of previous operations. Using the properties of the digital root, DR(Y)=DR(a*b+accu)=DR(DR(a)*DR(b)+DR(accu)). This shows that the digital root can be used as a checksum for the MAC operation of multiply-accumulate circuit 421 with input parameters a and b. The error detection circuitry of FIG. 4 performs the checksum operation of the MAC operation of the first multiply-accumulate circuit 421.

DR circuitry 425 produces the digital roots of the input operands A and B, DR(A) and DR(B), and outputs the digital roots to the second multiply-accumulate circuit 423. The second multiply-accumulate circuit 423 performs the MAC operation on digital roots of the operands A and B. As operands are fed into the first multiply-accumulate circuit 421, digital roots of the operands are fed into the second multiply-accumulate circuit 423 and the MAC operation of the second multiply-accumulate circuit 423 is performed in parallel with the MAC operation of the first multiply-accumulate circuit 423.

DR circuitry 427 produces a first result digital root that is the digital root of the output of the first multiply-accumulate circuit 421, and DR circuitry 429 produces a second result digital root that is the digital root of the output of the second multiply-accumulate circuit 423. The error detection circuitry includes a compare circuit 431 to compare the digital root produced by DR circuitry 427 to the digital root produced by DR circuitry 429. If the digital roots match, there is not an error in the MAC operation of the PIM block 109. If the digital roots do not match, an error is detected in the MAC operation of the PIM block 109.

In some examples, the error detection circuitry includes overflow detection circuitry 433 to detect overflow in the accumulators the multiply-accumulate circuits. If the PIM operation is performed in response to a command from the host device 105, the memory controller 111 may return the result of the PIM operation of each PIM block 109 to the host device 105 when no error is detected by the error detection circuitry. In certain examples, the result of the PIM operation for each PIM block 109 is stored in the memory array and read by the host device. If the error detection circuitry detects an error (either an error in the digital root computation or an overflow), the memory controller 111 may return an error status to the host device 105 indicating the error.

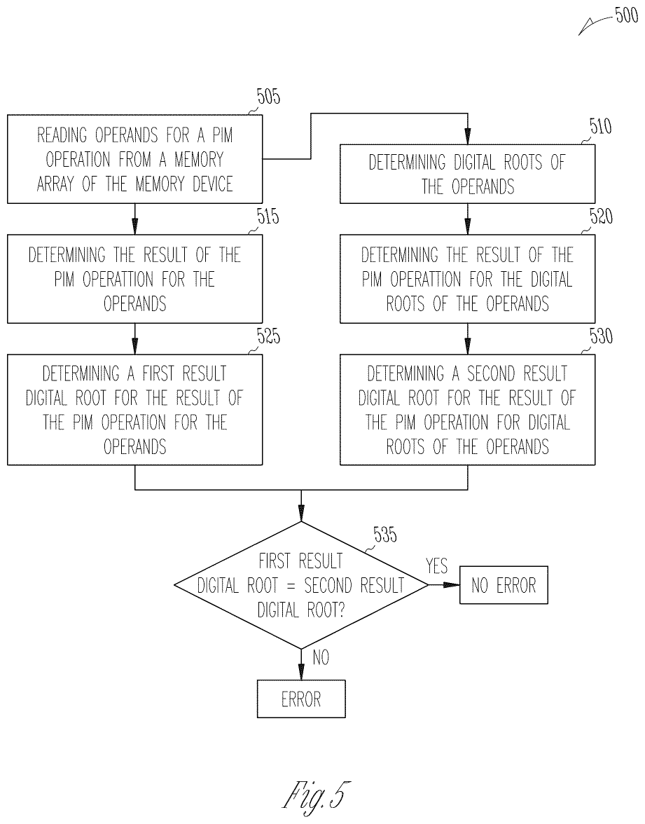

FIG. 5 is a flow diagram of an example of a method 500 of operating a memory device (e.g., a memory device 107 of memory system 110 in FIG. 1). The method includes performing a Processing in Memory operation using PIM circuitry of the memory device. The PIM operation may be performed by the memory device in response to a command from a host device.

At block 505, a memory controller of the memory system reads operands for the PIM operation from a memory array of the memory device. The PIM operation may involve inputting a pipeline of respective operands into the PIM circuitry. For instance, the PIM circuitry may perform an in-memory multiply-accumulate operation as in the example of FIG. 3 where there are two respective operands (operand A and operand B) input into the PIM circuitry. The memory controller may provide a pipeline of each of the respective operands to the PIM circuitry. In certain examples, the memory controller stores the respective operands in respective memory banks and reads the operands from the respective memory banks. For instance, in the example of FIG. 3, the memory controller stores and reads the A operands from one memory bank (memory bank 102A) and stores and reads the B operands from another memory bank (memory bank 102B).

At block 510, the digital roots for the operands are determined. The memory controller may provide a pipeline of operands to digital root circuitry as the pipeline of operands are provided to the PIM circuitry.

At block 515, the result of the PIM operation for the operands is determined. In the example of FIG. 3, the result of a memory-accumulate operation is determined for the operands read from the memory banks. The result may be computed for a pipeline of operands input to the PIM circuitry. At block 520, the result of the PIM operation for the digital roots of the operands is determined. The PIM circuitry may include second PIM circuitry to determine the PIM operation for the digital roots of the operands. In the example of FIG. 4, the PIM circuitry includes a first multiply-accumulate circuit to produce a result for the operands, and a second multiply-accumulate circuit to produce a result for the digital roots of the operands.

Because the second PIM circuitry operates on digital roots of the operands, the second PIM circuitry may be smaller in area and operate on less bits than the first PIM circuitry. For instance, if the PIM circuitry includes multiply-accumulate circuits, the first multiply-accumulate circuit may include an 8-bit or 16-bit multiply circuit to multiply operands, the second multiply-accumulate circuit may only need a 4-bit multiply circuit to multiple the digital roots.

At block 525, a first result digital root is determined for the result of the PIM operation for the operands, and at block 530 a second result digital root is determined for the result of the PIM operation for the digital roots of the operands. The second result digital root is a check on the result of the PIM operation for the operands.

At block 535, the first result digital root is compared to the second result digital root to detect an error in the PIM operation. If the first and second result digital roots are the same, then there was no error in the PIM operation. The memory controller may return the result or results of the PIM operation to the host device if no error occurred, or the result may be stored in the memory array and read by the host device using a read command. If the first and second result digital roots are different, then an error occurred in the PIM operation. The memory controller may return an error status to the host device when an error occurs. In some examples, the memory controller stores the result of the PIM operation with the error status. If the PIM operation is a multiply-accumulate operation, the PIM circuitry can include overflow detection circuitry to detect overflow in the accumulators of the multiply-accumulate circuits. Overflow errors may be handled similarly to errors in the arithmetic operation.

The system, methods, and devices described herein provide techniques to protect in-memory processing from errors that may not be detected using conventional approaches. The errors are detectable for the in-memory processing as the in-memory processing provides outputs.

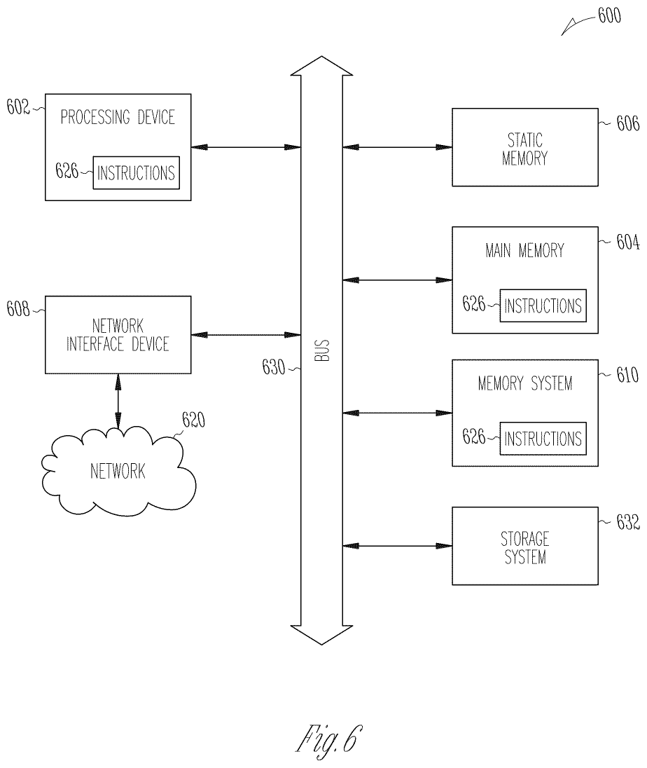

FIG. 6 illustrates a block diagram of an example machine 600 (e.g., a computing system) upon which any one or more of the techniques (e.g., methodologies) discussed herein may perform. In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 600 may include a processing device 602 (e.g., a hardware processor, a central processing unit (CPU), a graphics processing unit (GPU), a hardware processor core, or any combination thereof, etc.), a main memory 604 (e.g., read-only memory (ROM), dynamic random-access memory (DRAM) such as synchronous DRAM (SDRAM) or Rambus DRAM (RDRAM), etc.), a static memory 606 (e.g., static random-access memory (SRAM), etc.), a memory system 610, and a storage system 632, some or all of which may communicate with each other via a communication interface (e.g., a bus) 630. One or both of the memory system 610 and storage system 632 may include processing in memory capability and may include processing circuitry.

The processing device 602 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 can be configured to execute instructions 626 for performing the operations and steps discussed herein. The computer system can further include a network interface device 608 to communicate over a network 620.

The memory system 610 can include a machine-readable storage medium (also known as a computer-readable medium) on which is stored one or more sets of instructions 626 or software embodying any one or more of the methodologies or functions described herein. The instructions 626 can also reside, completely or at least partially, within the main memory 604 or within the processing device 602 during execution thereof by the computer system, the main memory 604 and the processing device 602 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 600 may further include a display unit, an alphanumeric input device (e.g., a keyboard), and a user interface (UI) navigation device (e.g., a mouse). In an example, one or more of the display units, the input device, or the UI navigation device may be a touch screen display. The machine 600 may include a signal generation device (e.g., a speaker), or one or more sensors, such as a global positioning system (GPS) sensor, compass, accelerometer, or one or more other sensors. The machine 600 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 626 (e.g., software, programs, an operating system (OS), etc.) or other data stored on the storage system 632 can be accessed by the main memory 604 for use by the processing device 602. The main memory 604 (e.g., DRAM) is typically fast, but volatile, and thus a different type of storage than the storage system 632 (e.g., an SSD), which is suitable for long-term storage, including while in an “off” condition. The instructions 626 or data in use by a user or the machine 600 are typically loaded in the main memory 604 for use by the processing device 602. When the main memory 604 is full, virtual space from the memory system 610 can be allocated to supplement the main memory 604; however, because the memory system 610 device is typically slower than the main memory 604, and write speeds are typically at least twice as slow as read speeds, use of virtual memory can greatly reduce user experience due to storage system latency (in contrast to the main memory 604, e.g., DRAM). Further, use of the storage system 632 for virtual memory can greatly reduce the usable lifespan of the storage system 632.

The instructions 626 may further be transmitted or received over a network 620 using a transmission medium via the network interface device 608 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®, IEEE 802.15.4 family of standards, peer-to-peer (P2P) networks, among others). In an example, the network interface device 608 may include one or more physical jacks (e.g., Ethernet, coaxial, or phone jacks) or one or more antennas to connect to the network 620. In an example, the network interface device 608 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” and “substrate” are used herein to refer generally to any structure on which integrated circuits are formed, and also to such structures during various stages of integrated circuit fabrication. The following detailed description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells (e.g., NAND strings of memory cells). As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

As used herein, directional adjectives, such as horizontal, vertical, normal, parallel, perpendicular, etc., can refer to relative orientations, and are not intended to require strict adherence to specific geometric properties, unless otherwise noted. For example, as used herein, a vertical structure need not be strictly perpendicular to a surface of a substrate but may instead be generally perpendicular to the surface of the substrate, and may form an acute angle with the surface of the substrate (e.g., between 60 and 120 degrees, etc.).

In some embodiments described herein, different doping configurations may be applied to a select gate source (SGS), a control gate (CG), and a select gate drain (SGD), each of which, in this example, may be formed of or at least include polysilicon, with the result such that these tiers (e.g., polysilicon, etc.) may have different etch rates when exposed to an etching solution. For example, in a process of forming a monolithic pillar in a 3D semiconductor device, the SGS and the CG may form recesses, while the SGD may remain less recessed or even not recessed. These doping configurations may thus enable selective etching into the distinct tiers (e.g., SGS, CG, and SGD) in the 3D semiconductor device by using an etching solution (e.g., tetramethylammonium hydroxide (TMCH)).

According to one or more embodiments of the present disclosure, a memory controller (e.g., a processor, controller, firmware, etc.) located internal or external to a memory device, is capable of determining (e.g., selecting, setting, adjusting, computing, changing, clearing, communicating, adapting, deriving, defining, utilizing, modifying, applying, etc.) that a memory rank or memory bank is in a cold state (e.g., recording wear cycles, counting operations of the memory device as they occur, tracking the operations of the memory device it initiates, evaluating the memory device characteristics corresponding to a cold state, etc.)

According to one or more embodiments of the present disclosure, a memory access device may be configured to provide cold state information to the memory device with each memory operation. The memory device control circuitry (e.g., control logic) may be programmed to change the power mode of the memory rank or memory bank according to its cold state.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

Example 1 includes subject matter (such as a memory device) comprising a memory array including multiple memory cells, processing in memory (PIM) circuitry configured to read operands from the memory and perform a PIM operation on the operands, and error detection circuitry. The error detection circuitry is configured to determine digital roots for the operands, determine a first result digital root for a result of the PIM operation for the operands, determine a second result digital root for a result of the PIM operation for the digital roots of the operands, and compare the first result digital root and the second result digital root to detect an error in the PIM operation.

In Example 2, the subject matter of Example 1 optionally includes PIM circuitry that includes first multiply-accumulate circuitry to perform a multiply-accumulate operation on the operands and produce a first multiply-accumulate result for the operands. The error detection circuitry optionally includes digital root circuitry configured to determine the digital roots of the operands, and second multiply-accumulate circuitry to perform a multiply-accumulate operation on the digital roots of the operands and produce a second multiply-accumulate result for the digital roots of the operands. The digital root circuitry is optionally configured to determine the first result digital root as a digital root of the first multiply-accumulate result and determine the second result digital root as a digital root of the second multiply-accumulate result.

In Example 3, the subject matter of Example 2 optionally includes second multiply-accumulate circuitry including an accumulator and overflow detection circuitry for the accumulator, and includes error detection circuitry configured to produce an indication of overflow error when an overflow of the accumulator of the second multiply-accumulate circuitry is detected.

In Example 4, the subject matter of one or any combination of Examples 1-3 optionally includes a memory controller configured to receive a command from a host device to perform the PIM operation, load the operands in the PIM circuitry, and return an error status to the host device when the first result digital root does not match the second result digital root.

In Example 5, the subject matter of Example 4, optionally includes a memory controller configured to return the result of the PIM operation for the operands when the first result digital root matches the second result digital root.

In Example 6, the subject matter of one or both of Examples 4 and 5 optionally includes a memory array including multiple memory banks and a memory controller configured to read the operands for the PIM operation from different memory banks.

In Example 7, the subject matter of one or any combination of Examples 1-6 optionally includes multiple PIM blocks. A PIM block includes the PIM circuitry, the error detection circuitry, and multiple memory banks. Each memory bank of the PIM block is to store a different operand for the PIM operation performed by the PIM circuitry of the PIM block.

Example 8 includes subject matter (such as a method of error detection in a memory device) or can optionally be combined with one or any combination of Examples 1-7 to include such subject matter, comprising reading operands for a processing in memory (PIM) operation from a memory array of the memory device, determining digital roots for the operands, determining the result of the PIM operation for the digital roots of the operands, determining a first result digital root for the result of the PIM operation for the operands, determining a second result digital root for the result of the PIM operation for the digital roots of the operands, and comparing the first result digital root and the second result digital root to detect an error in the PIM operation.

In Example 9, the subject matter of Example 8 optionally includes determining an in-memory multiply-accumulate operation for the operands, and determining an in-memory multiply-accumulate operation for the digital roots of the operands.

In Example 10, the subject matter of Example 9 optionally includes producing an indication of overflow error when detecting an overflow of an accumulator for the in-memory multiply-accumulate operation for the digital roots of the operands.

In Example 11, the subject matter of one or any combination of Examples 8-10 optionally includes performing the PIM operation in response to a host command from a host device, returning an error indication to the host device when the comparing the first result digital root and the second result digital root indicates an error, and returning the result of the PIM operation for the operands to the host device when an error is not detected by the comparing of the first result digital root and the second result digital root.

In Example 12, the subject matter of one or any combination of Examples 8-11 optionally includes storing the result of the PIM operation for the operands in the memory array with an error indication when the comparing the first result digital root and the second result digital root indicates an error.

In Example 13, the subject matter of one or any combination of Examples 8-12 optionally includes determining multiple results for multiple PIM operations performed in parallel by multiple PIM blocks of the memory device in response to a command from a host device, determining first result digital roots for the results of the multiple PIM operations for the operands and second result digital roots for the result of the PIM operations for the digital roots of the operands, and comparing the first result digital roots and the second result digital roots to detect errors in the PIM operation of each PIM block.

In Example 14, the subject matter of Example 13 optionally includes reading each operand from a separate memory bank of the memory array for each PIM block.

Example 15 includes subject matter (such as an arithmetic circuit) or can optionally be combined with one or any combination of Examples 1-4 to include such subject matter, comprising first multiply-accumulate circuitry configured to perform a multiply-accumulate operation on operands stored in a memory array and produce a first multiply-accumulate result for the operands and error detection circuitry. The error detection circuitry includes digital root circuitry configured to determine digital roots of the operands and second multiply-accumulate circuitry to perform a multiply-accumulate operation on the digital roots of the operands and produce a second multiply-accumulate result for the digital roots of the operands. The digital root circuitry is optionally configured to determine a first result digital root as a digital root of the first multiply-accumulate result and determine a second result digital root as a digital root of the second multiply-accumulate result and the error detection circuitry is optionally configured to compare the first result digital root and the second result digital root to detect an error in the first multiply-accumulate result for the operands.

In Example 16, the subject matter of Example 15 optionally includes first multiply-accumulate circuitry and the second multiply-accumulate circuitry that include overflow detection circuitry to detect overflow in accumulators of the multiply-accumulate circuitry.

In Example 17, the subject matter of one or both of Examples 15 and 16 optionally includes second multiply-accumulate circuitry configured to produce the second multiply-accumulate result for the digital roots of the operands in parallel with the first multiply-accumulate circuitry producing the first multiply-accumulate result for the operands.

In Example 18, the subject matter of one or any combination of Examples 15-17 optionally includes the digital root circuitry configured to determine the digital roots of the operands as the operands are read from memory and applied to the first multiply-accumulate circuitry.

In Example 19, the subject matter of one or any combination of Examples 15-18 optionally includes first multiply-accumulate circuitry and the second multiply-accumulate circuitry each include a base-10 multiplier circuit.

In Example 20, the subject matter of one or any combination of Examples 15-18 optionally includes first multiply-accumulate circuitry and the second multiply-accumulate circuitry each include a base-16 multiplier circuit.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device comprising:
a memory array including multiple memory cells;
processing in memory (PIM) circuitry configured to read operands from the memory and perform a PIM operation on the operands; and
error detection circuitry configured to:
determine digital roots for the operands;
determine a first result digital root for a result of the PIM operation for the operands;
determine a second result digital root for a result of the PIM operation for the digital roots of the operands; and
compare the first result digital root and the second result digital root to detect an error in the PIM operation.

2. The memory device of claim 1,
wherein the PIM circuitry includes:
first multiply-accumulate circuitry to perform a multiply-accumulate operation on the operands and produce a first multiply-accumulate result for the operands;
wherein the error detection circuitry includes:
digital root circuitry configured to determine the digital roots of the operands;
second multiply-accumulate circuitry to perform a multiply-accumulate operation on the digital roots of the operands and produce a second multiply-accumulate result for the digital roots of the operands; and
wherein the digital root circuitry is further configured to determine the first result digital root as a digital root of the first multiply-accumulate result and determine the second result digital root as a digital root of the second multiply-accumulate result.

3. The memory device of claim 2,
wherein the second multiply-accumulate circuitry includes an accumulator and overflow detection circuitry for the accumulator; and
wherein the error detection circuitry is configured to produce an indication of overflow error when an overflow of the accumulator of the second multiply-accumulate circuitry is detected.

4. The memory device of claim 1, including a memory controller configured to:
receive a command from a host device to perform the PIM operation;
load the operands in the PIM circuitry; and
return an error status to the host device when the first result digital root does not match the second result digital root.

5. The memory device of claim 4, wherein the memory controller is configured to return the result of the PIM operation for the operands when the first result digital root matches the second result digital root.

6. The memory device of claim 4,
wherein the memory array includes multiple memory banks, and the memory controller is configured to read the operands for the PIM operation from different memory banks.

7. The memory device of claim 1, including:
multiple PIM blocks, wherein a PIM block includes the PIM circuitry, the error detection circuitry, and multiple memory banks, each memory bank of a PIM block to store a different operand for the PIM operation performed by the PIM circuitry of the PIM block.

8. A method of error detection in a memory device, the method comprising:
reading operands for a processing in memory (PIM) operation from a memory array of the memory device;
determining digital roots for the operands;
determining a result of the PIM operation for the operands;
determining the result of the PIM operation for the digital roots of the operands;
determining a first result digital root for the result of the PIM operation for the operands;
determining a second result digital root for the result of the PIM operation for the digital roots of the operands; and
comparing the first result digital root and the second result digital root to detect an error in the PIM operation.

9. The method of claim 8,
wherein the determining the result of the PIM operation for the operands includes determining an in-memory multiply-accumulate operation for the operands; and
wherein the determining the result of the PIM operation for the digital roots of the operands includes determining an in-memory multiply-accumulate operation for the digital roots of the operands.

10. The method of claim 9, including producing an indication of overflow error when detecting an overflow of an accumulator for the in-memory multiply-accumulate operation for the digital roots of the operands.

11. The method of claim 8, including:
performing the PIM operation in response to a host command from a host device;
returning an error indication to the host device when the comparing the first result digital root and the second result digital root indicates an error; and
returning the result of the PIM operation for the operands to the host device when an error is not detected by the comparing of the first result digital root and the second result digital root.

12. The method of claim 8, including storing the result of the PIM operation for the operands in the memory array with an error indication when the comparing the first result digital root and the second result digital root indicates an error.

13. The method of claim 8, wherein the determining a result of the PIM operation includes:
determining multiple results for multiple PIM operations performed in parallel by multiple PIM blocks of the memory device in response to a command from a host device;
determining first result digital roots for the results of the multiple PIM operations for the operands and second result digital roots for the result of the PIM operations for the digital roots of the operands; and
comparing the first result digital roots and the second result digital roots to detect errors in the PIM operation of each PIM block.

14. The method of claim 13, wherein the reading the operands includes reading each operand from a separate memory bank of the memory array for each PIM block.

15. An arithmetic circuit comprising:
first multiply-accumulate circuitry configured to perform a multiply-accumulate operation on operands stored in a memory array and produce a first multiply-accumulate result for the operands; and
error detection circuitry including:
digital root circuitry configured to determine digital roots of the operands; second multiply-accumulate circuitry to perform a multiply-accumulate operation on the digital roots of the operands and produce a second multiply-accumulate result for the digital roots of the operands; and
wherein the digital root circuitry is further configured to determine a first result digital root as a digital root of the first multiply-accumulate result and determine a second result digital root as a digital root of the second multiply-accumulate result; and
wherein the error detection circuitry is configured to compare the first result digital root and the second result digital root to detect an error in the first multiply-accumulate result for the operands.

16. The arithmetic circuit of claim 15, wherein the first multiply-accumulate circuitry and the second multiply-accumulate circuitry include overflow detection circuitry to detect overflow in accumulators of the multiply-accumulate circuitry.

17. The arithmetic circuit of claim 15,
wherein the second multiply-accumulate circuitry produces the second multiply-accumulate result for the digital roots of the operands in parallel with the first multiply-accumulate circuitry producing the first multiply-accumulate result for the operands.

18. The arithmetic circuit of claim 15, wherein the digital root circuitry determines the digital roots of the operands as the operands are read from memory and applied to the first multiply-accumulate circuitry.

19. The arithmetic circuit of claim 15, wherein the first multiply-accumulate circuitry and the second multiply-accumulate circuitry each include a base-10 multiplier circuit.

20. The arithmetic circuit of claim 15, wherein the first multiply-accumulate circuitry and the second multiply-accumulate circuitry each include a base-16 multiplier circuit.
